(19) United States
(12) Patent Application Publication
(10) Pub. No.: US 2020/0020512 A1
(43) Pub. Date: Jan. 16, 2020

(54) CHAMBER CLEANING PROCESS

(71) Applicant: Applied Materials, Inc., Santa Clara, CA (US)

(72) Inventors: Weiting CHEN, Taipei City (TW); Lynn YANG, Santa Clara, CA (US); Christy PAN, Santa Clara, CA (US); Beom Soo PARK, San Jose, CA (US); Young-Jin CHOI, San Jose, CA (US); Max CHANG, Santa Clara, CA (US)

(21) Appl. No.: 16/035,431

(22) Filed: Jul. 13, 2018

(51) Int. Cl. H01J 37/32; C23C 16/44; C23C 16/50; B08B 7/00

(52) U.S. Cl. CPC H01J 37/32862; C23C 16/4405; H01J 2237/24507; B08B 7/0035; H01J 2237/3321; C23C 16/50

(57) ABSTRACT

A method and apparatus for obtaining at least one normalized baseline spectrum for a processing volume of a processing chamber; calculating a distribution value of the normalized baseline spectrum; obtaining a plurality of normalized cleaning process spectrums; calculating a distribution function of the plurality of normalized cleaning process spectrums; comparing the distribution value to the distribution function; and determining an end point by identifying when the distribution function approaches the distribution value. A method includes: initiating a cleaning process in a processing chamber, flowing a cleaning gas into a processing volume of the processing chamber; obtaining a normalized baseline spectrum; measuring a plurality of intensity spectrums; calculate a plurality of normalized cleaning process spectrums; comparing a distribution value of the normalized baseline spectrum to a distribution function of the plurality of normalized cleaning process spectrums; and determining an end point by identifying when the distribution function approaches the distribution value.

### BACKGROUND

### Field

Embodiments disclosed herein generally relate to apparatus and methods for cleaning a processing chamber, and more specifically, to methods and apparatus facilitating detection of the end point of a chamber cleaning process.

### Description of the Related Art

One of the steps in the fabrication of modern semiconductor devices is the formation of a thin film on a semiconductor substrate by chemical reaction of gas. Such a deposition process is referred to as chemical vapor deposition or CVD. Processes include plasma-enhanced CVD (PECVD) techniques.

The surface upon which a CVD layer is deposited may contain contaminants, such as particulate or film deposits from chamber walls or components and/or from prior processes. The presence of contaminants may affect the absorption of precursors and slow or inhibit the deposition rate of the CVD layer. Contamination within the chamber is typically controlled by periodically cleaning the chamber using cleaning gas which are excited to inductively or capacitively-coupled plasmas. Cleaning gas may bind the contaminants in order to form stable volatile products which can be exhausted from the chamber, thereby cleaning the process environment. So that all or nearly all of the contaminants in a chamber are removed, sufficient cleaning gas must be provided, and sufficient time must elapse, to allow binding reactions between the cleaning gas and all or nearly all of the contaminants.

Reactions binding cleaning gas to contaminants may generate electromagnetic radiation. The electromagnetic radiation may be in the visible light spectrum. Therefore, reactions binding cleaning gas to contaminants may be identified by a visible “glow.” Once all or nearly all of the contaminants have bound to cleaning gas (assuming sufficient cleaning gas has been provided), the end point of the chamber cleaning process may be identified by cessation of the glow. However, conventional methods (e.g., visual detection or specified-wavelength measurement) of identification of an end point may be inaccurate, imprecise, and/or inconsistent. Too short of a time period for a chamber cleaning process may result in a contaminated processing environment, while too long of a time period for a chamber cleaning process may be costly and inefficient. What is needed are methods and apparatus to more accurately, precisely, and consistently identify the end point of a chamber cleaning process.

### SUMMARY

In one or more embodiments disclosed herein, a method includes: obtaining at least one normalized baseline spectrum for a processing volume of a processing chamber; calculating a distribution value of the at least one normalized baseline spectrum; obtaining a plurality of normalized cleaning process spectrums for the processing volume over a time period during a cleaning process of the processing chamber; calculating a distribution function of the plurality of normalized cleaning process spectrums; comparing the distribution value to the distribution function over the time period; and determining an end point for the cleaning process by identifying when the distribution function approaches the distribution value.

In one or more embodiments disclosed herein, a method includes: initiating a first processing-cleaning cycle for a processing chamber, wherein: the first processing-cleaning cycle comprises a first over-cleaning period, and a first plurality of baseline spectrums for a processing volume of the processing chamber are measured during the first over-cleaning period; after the first processing-cleaning cycle, initiating a second processing-cleaning cycle for the processing chamber, wherein: the second processing-cleaning cycle comprises a second cleaning process, and a second plurality of cleaning process spectrums for the processing volume are measured during the second cleaning process; and determining a second end point for the second cleaning process by: calculating a distribution function of a second plurality of normalized cleaning process spectrums from the first plurality of baseline spectrums and the second plurality of cleaning process spectrums; calculating a distribution value of a second normalized baseline spectrum from the first plurality of baseline spectrums; comparing the distribution value of the second normalized baseline spectrum to the distribution function of the second plurality of normalized cleaning process spectrums; and identifying when the distribution function of the second plurality of normalized cleaning process spectrums approaches the distribution value of the second normalized baseline spectrum.

In one or more embodiments disclosed herein, a method includes: initiating a cleaning process in a processing chamber, the cleaning process comprising flowing a cleaning gas into a processing volume of the processing chamber; obtaining a normalized baseline spectrum for the processing volume of a processing chamber; measuring a plurality of intensity spectrums for the processing volume during the cleaning process; using the plurality of intensity spectrums to calculate a plurality of normalized cleaning process spectrums for the processing volume; comparing a distribution value of the normalized baseline spectrum to a distribution function of the plurality of normalized cleaning process spectrums; and determining an end point for the cleaning process by identifying when the distribution function of the plurality of normalized cleaning process spectrums approaches the distribution value of the normalized baseline spectrum.

### BRIEF DESCRIPTION OF THE DRAWINGS

So that the manner in which the above-recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is a schematic cross-sectional view of one embodiment of a processing system having a radiation detection device.

FIGS. 2A and 2B are illustrations of chamber cleaning processes according to embodiments disclosed herein.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

Embodiments of the present invention generally relate to the fabrication of integrated circuits. More particularly, the embodiments described herein provide cleaning techniques for a plasma chamber utilized in the manufacture of integrated circuits. During manufacturing processes (e.g., plasma-enhanced chemical vapor deposition (PECVD)), material (e.g., amorphous silicon) may contaminate the chamber walls or components. During chamber cleaning processes, cleaning gas (e.g., fluorine radicals) may be used to react with and/or remove contaminants from the chamber. If insufficient cleaning gas is provided, or if insufficient time is allowed for the cleaning process, contaminants may remain, resulting in under cleaning of the chamber. However, excessive chamber cleaning may be costly and/or time consuming.

The end point of a chamber cleaning process occurs when the level of contaminates (e.g., impurities and/or dopant material) remaining in the chamber, on chamber walls, and/or on components drops below a desired amount. In general, an end point may be reached when contaminant particulate level drops, for example, to no more than about 20 to about 50 particles remaining from a single deposition process. In some embodiments, each contaminant particle is approximated about 1 nm to about 3 nm in size. In general, an end point may be reached when contamination coverage drops, for example, to cover no more than about 1% to about 5% of the total processing volume and/or chamber equipment. In some embodiments, the contamination coverage may be a film having a thickness of between about 800 Å and about 1200 Å. Embodiments disclosed herein provide methods to determine when the end point of a chamber cleaning process occurs. In some embodiments, the methods identify the end point by measuring broad-spectrum signals to provide more redundancy and/or better quality control than conventional methods. Embodiments disclosed herein, unlike conventional methods, beneficially provide methods applicable to a variety of processing materials (e.g., substrates and/or film materials, such as SiN, SiO, aSi), a variety of processing apparatus, and a variety of processing methods or formulae.

Embodiments disclosed herein may provide more accurate, more precise, and/or more consistent end point detection compared to conventional methods. For example, some conventional methods determine a cleaning process end point by measuring radiation at a few (less than 10) specified wavelengths and seeking a maximum, minimum, threshold, or value change of a specified amount. (For example, a clean spectrum for SiN typically exhibits 6 peaks, a clean spectrum for SiO typically exhibits 4 peaks, and a clean spectrum for aSi typically exhibits 2 peaks.) Determining an end point by specified-wavelength measurement may cause: (1) complications in meeting series-criteria, (2) difficulty in adjusting settings when the processing material is changed, and/or (3) difficulty in adjusting settings when the cleaning method or formula is changed. Embodiments disclosed herein utilize spectrum measurements that are not limited to peaks, maxima, or minima, and that include anywhere between 100 to 1000 different wavelength measurements. Such embodiments may beneficially provide a broad-spectrum signal to determine a cleaning process end point. Embodiments disclosed herein may simplify adjustments to setting/criteria when the processing material is changed. Embodiments disclosed herein may be applicable to different processing equipment, methods, and/or formulae.

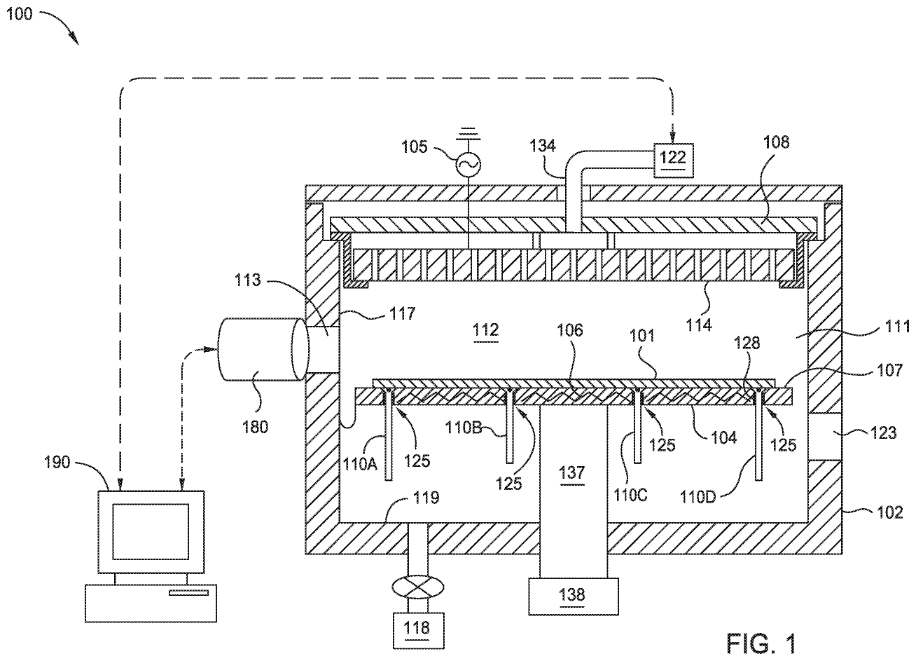

FIG. 1 is a schematic cross-sectional view of one embodiment of a processing system 100. In one embodiment, the processing system 100 is configured to process flexible media, such as a large area substrate 101, using plasma to form structures and devices on the large area substrate 101. The structures formed by the processing system 100 may be adapted for use in the fabrication of liquid crystal displays (LCD's), flat panel displays, organic light emitting diodes (OLED's), or photovoltaic cells for solar cell arrays. The substrate 101 may be thin sheet of metal, plastic, organic material, silicon, glass, quartz, or polymer, among others suitable materials. The substrate 101 may have a surface area greater than about 1 square meter, such as greater than about 2 square meters. The structures may include one or more junctions used to form part of a thin film photovoltaic device or solar cell. In another embodiment, the structures may be a part of a thin film transistor (TFT) used to form a LCD or TFT type device. It is also contemplated that the processing system 100 may be adapted to process substrates of other sizes and types, and may be used to fabricate other structures.

As shown in FIG. 1, the processing system 100 generally comprises a chamber body 102 including a sidewall 117, a bottom 119, and a backing plate 108 defining a processing volume 111. A lid may be disposed over the backing plate 108. A pedestal or substrate support 104 is disposed in the processing volume 111 opposing a showerhead assembly 114. The substrate support 104 is adapted to support the substrate 101 on an upper or support surface 107 during processing. The substrate support 104 is also coupled to an actuator 138 via a hollow shaft 137. The actuator is configured to move the substrate support 104 at least vertically to facilitate transfer of the substrate 101 and/or adjust a distance between the substrate 101 and a showerhead assembly 114. One or more support pins 110A-110D extend through the substrate support 104 through respective housings 125. Each of the support pins 110A-110D are movably disposed within a dedicated support device, such as the housing 125 that is disposed within openings 128 formed in the substrate support 104. Each of the housings 125 may be a roller bushing or a simple tubular bushing adapted to movably support a support pin, such as one of the support pins 110A-110D. An opening 123 is formed in the sidewall 117 and may be used to transfer substrates between the substrate support 104 and a transfer chamber or load lock chamber (both not shown).

A window 113 is located in the sidewall 117 to provide radiation transmission between the processing volume 111 and the exterior of the chamber body 102. For example, the window 113 may be quartz or glass. In some embodiments, the window 113 may be located in sidewall 117 on the opposite side of the processing volume 111 from opening 123. In some embodiments, window 113 may be transparent to visible light radiation, for example electromagnetic radiation having wavelengths between about 300 nm and about 800 nm. In some embodiments, window 113 may be made up of a plurality of window panes, each pane extending through sidewall 117 and distinguished by varying transparencies. For example, a first pane may be transparent to electromagnetic radiation having wavelengths between about 300 nm and about 400 nm, and a second pane may be transparent to electromagnetic radiation having wavelengths between about 700 nm and about 800 nm. As another example, a third pane may be transparent to infrared radiation having wavelengths between about 700 nm and about 1 millimeter. As yet another example, a fourth pane may be 50% opaque to visible light, while a fifth pane may be 80% opaque to visible light.

In some embodiments, a radiation detection device 180 may be coupled to window 113 on the exterior of the chamber body 102. The radiation detection device 180 may be either permanently or removably coupled to window 113. The radiation detection device 180 may be either directly or indirectly coupled to window 113. In some embodiments, the radiation detection device 180 may be coupled to a portion of window 113 (e.g., to a subset of the panes of window 113), leaving another portion of window 113 exposed to the exterior of the chamber body 102. The radiation detection device 180 may be an optical detector, a spectrometer, a photocell, or other radiation detector. The radiation detection device 180 may be configured to detect radiation transmitted from processing volume 111 and through window 113. The radiation detection device 180 may be configured to detect and/or measure electromagnetic radiation, for example electromagnetic radiation having wavelengths between about 300 nm and about 800 nm. Radiation detection device 180 may detect radiation at a variety of wavelengths. It is currently believed that detection of infrared electromagnetic radiation by radiation detection device 180 (e.g., for the purpose of end point identification) may be subject to more noise, such as from chamber temperature variations, than visible light. In some embodiments, radiation transmitted from processing volume 111 through window 113 may follow a waveguide (e.g., optical fiber) to reach radiation detection device 180.

A gas source 122 is coupled by a conduit 134 to deliver gas (e.g., processing gas, precursor gas, purge gas, carrier gas, or cleaning gas) through the showerhead assembly 114 and into the processing volume 111. The processing system 100 also includes an exhaust system 118 configured to apply and/or maintain negative pressure to the processing volume 111. A radio frequency (RF) power source 105 is coupled to the showerhead assembly 114 to facilitate formation of a plasma in a processing region 112. The processing region 112 is generally defined between the showerhead assembly 114 and the support surface 107 of the substrate support 104.

Using a processing gas from the gas source 122, the processing system 100 may be configured to deposit a variety of materials on the large area substrate 101, including but not limited to dielectric materials (e.g., SiO₂, SiOₓN_{y}, derivatives thereof or combinations thereof), semiconductive materials (e.g., Si and dopants thereof), and/or barrier materials (e.g., SiNₓ, SiOₓN_{y} or derivatives thereof). Specific examples of dielectric materials and semiconductive materials that are formed or deposited by the processing system 100 onto the large area substrate may include epitaxial silicon, polycrystalline silicon, amorphous silicon, microcrystalline silicon, silicon germanium, germanium, silicon dioxide, silicon oxynitride, silicon nitride, dopants thereof (e.g., B, P, or As), derivatives thereof, or combinations thereof. The processing system 100 is also configured to receive gas such as argon, hydrogen, nitrogen, helium, or combinations thereof, for use as a purge gas or a carrier gas (e.g., Ar, H₂, N₂, He, derivatives thereof, or combinations thereof). One example of depositing silicon thin films on the large area substrate 101 using the system 100 may be accomplished by using silane as the precursor gas in a hydrogen carrier gas. The showerhead assembly 114 is generally disposed opposing the substrate support 104 in a substantially parallel manner to facilitate plasma generation therebetween.

A temperature control device 106 may also be disposed within the substrate support 104 to control the temperature of the substrate 101 before, during, or after processing. In one aspect, the temperature control device 106 comprises a heating element to preheat the substrate 101 prior to processing. In this embodiment, the temperature control device 106 may heat the substrate support 104 to a temperature between about 200° C. and 250° C. During processing, temperatures in the processing region 112 may reach or exceed 400° C., and the temperature control device 106 may comprise one or more coolant channels to cool the substrate 101. In another aspect, the temperature control device 106 may function to cool the substrate 101 after processing. Thus, the temperature control device 106 may be coolant channels, a resistive heating element, or a combination thereof. Electrical leads for the temperature control device 106 may be routed to a power source and/or a controller through the hollow shaft 137.

During a chamber cleaning process, gas source 122 may provide cleaning gas (e.g., NF) to the processing volume 111. An energy source, such as a remote plasma source (RPS) or a radio frequency (RF) source, may be used to dissociate at least a portion of the cleaning gas molecules, thereby providing a mixture of atomic and molecular cleaning gas. The cleaning gas may react (e.g., bind) with contaminants to produce electromagnetic radiation in processing volume 111. Radiation detection device 180 may detect radiation produced by the reactions and transmitted from processing volume 111 through window 113. Radiation detection device 180 may measure the intensity of the detected radiation at various wavelengths and at various times. In some embodiments, radiation detection device 180 may measure broad-spectrum (at least about 100 to 1000 or more different wavelengths) signals of the intensity of the detected radiation.

The radiation detection device 180 and/or a data processing device 190 may utilize the intensity measurements to produce intensity spectrums. For example, the radiation detection device 180 may transmit the intensity measurements to the data processing device 190. As another example, the radiation detection device 180 may produce an intensity spectrum at a particular instant and transmit that instantaneous intensity spectrum to data processing device 190. As another example, radiation detection device 180 may transmit a plurality of instantaneous intensity spectrums to data processing device 190. In some embodiments, data processing device 190 may poll radiation detection device 180 or otherwise communicate data and/or control signals therebetween.

The data processing device 190 may receive, analyze, and/or store intensity measurements and intensity spectrums from radiation detection device 180. Based on the received, analyzed, and/or stored information, the data processing device 190 may communicate with gas source 122. For example, data processing device 190 may identify the end point of a cleaning process. In some embodiments, in response to identification of the end point of a cleaning process, data processing device 190 may send control signals to gas source 122 to reduce or cease flow of cleaning gas to processing volume 111. In some embodiments, data processing device 190 may communicate data and/or control signals with various other components of processing system 100 (e.g., temperature control device 106).

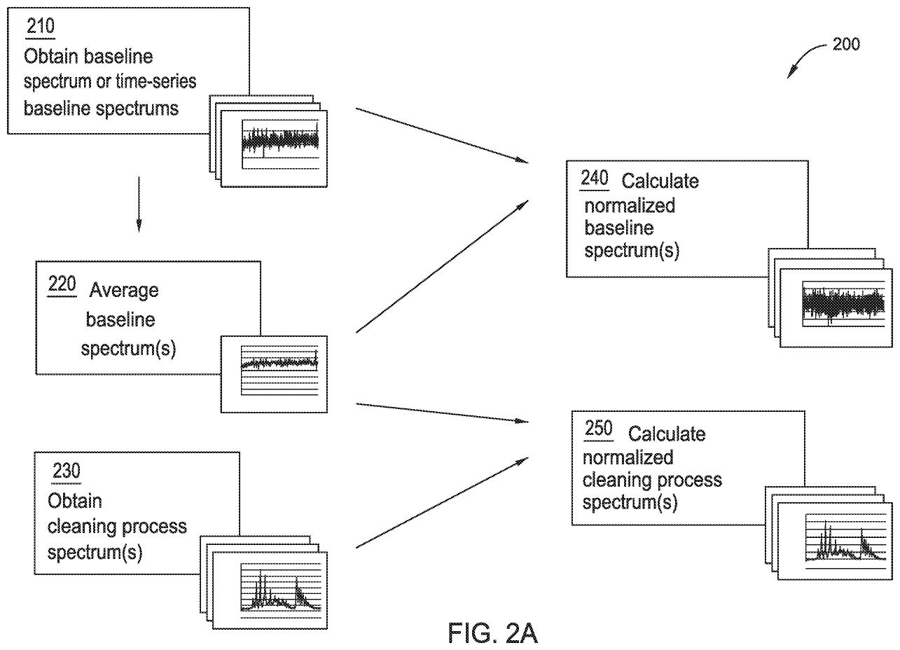

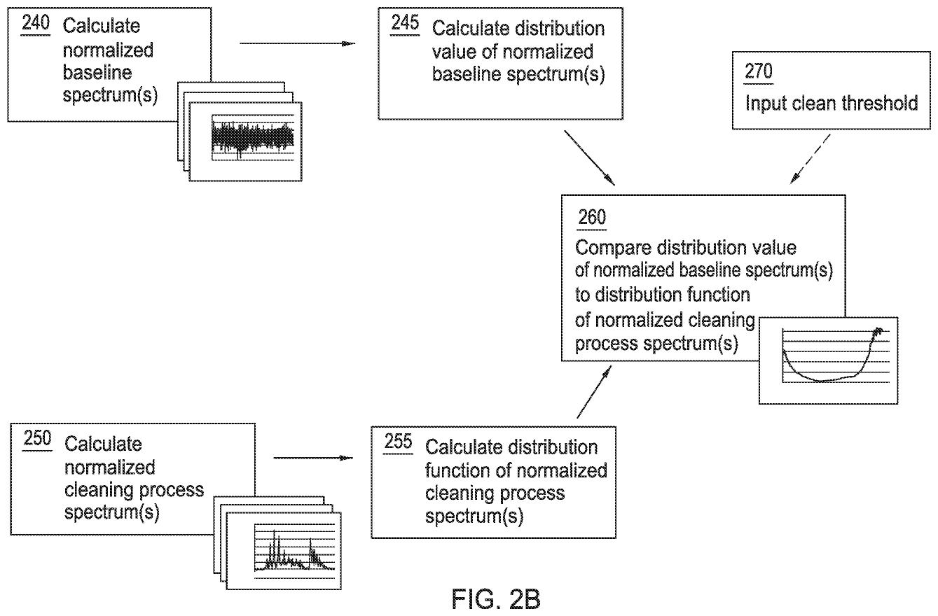

FIG. 2A illustrates a portion of a cleaning process 200 according to embodiments disclosed herein. Cleaning process 200 begins at box 210 wherein one or more baseline spectrum(s) are obtained. A baseline spectrum represents the detectable radiation in processing volume 111 when binding reactions between cleaning gas and contaminants are minimal or nonexistent. As used herein, obtaining data shall mean any method or combination of methods of acquiring, collecting, or accessing data, including, for example, directly measuring or sensing a physical property, receiving transmitted data, selecting data from a group of physical sensors, identifying data in a data record, and retrieving data from one or more data libraries. For example, a baseline spectrum may be obtained by utilizing radiation detection device 180 to measure radiation in processing volume 111 when the chamber is “dark” (e.g., before cleaning gas is introduced or after cleaning gas and/or contaminants are depleted). For example, a baseline spectrum may be obtained during an idle step of processing, during a stable-flow step before deposition, or during an over-cleaning period. As used herein, an over-cleaning period is generally a period of time, typically no more than 50% of the total cleaning process period, near the end of a cleaning process. During the over-cleaning period, cleaning gas and/or contaminants are expected to be depleted. A cleaning process may include an over-cleaning period as a margin of error, for example to allow for the possibility of additional reactions between the cleaning gas and contaminants. A baseline spectrum may indicate radiation noise and/or background radiation inherent in the processing volume 111. At box 210, a time-series of baseline spectrums may be obtained. For example, the baseline spectrums may be obtained over a time period of about 3 seconds to about 15 seconds. Each baseline spectrum in the time-series of baseline spectrums represents an instantaneous broad-spectrum signal measurement of radiation intensity in the processing volume 111. Each baseline spectrum may be represented as a graph of intensity as a function of wavelength.

Cleaning process 200 continues at box 220 wherein the baseline spectrum(s) obtained at box 210 are averaged. For example, the time-series of baseline spectrums may be averaged to produce an average baseline spectrum. It should be understood that radiation noise may vary depending on targeted cleaning conditions, equipment type, equipment age and usage characteristics, ambient temperature or pressure, etc. Averaging baseline spectrums may provide a more stable estimate of background radiation than would be available from a single baseline spectrum.

Also illustrated at FIG. 2A, one or more cleaning process spectrum(s) may be obtained at box 230. A cleaning process spectrum represents the detectable radiation in processing volume 111 when binding reactions between cleaning gas and contaminants are occurring or expected to occur. For example, a cleaning process spectrum may be obtained by utilizing radiation detection device 180 to measure radiation in processing volume 111 when both cleaning gas and contaminants are present (or expected to be present) in processing volume 111. A cleaning process spectrum may indicate radiation resulting from binding reactions between the cleaning gas and the contaminants. At box 230, a time-series of cleaning process spectrums may be obtained. For example, the cleaning process spectrums may be obtained over a time period of about 3 seconds to about 15 seconds during the cleaning process. Each cleaning process spectrum in the time-series of cleaning process spectrums represents an instantaneous broad-spectrum signal measurement of radiation intensity in the processing volume 111. Each cleaning process spectrum may be represented as a graph of intensity as a function of wavelength.

Also illustrated at FIG. 2A, cleaning process 200 continues at box 240 wherein the baseline spectrum(s) obtained at box 210 are normalized. For example, the average baseline spectrum may be subtracted from each of the time-series of baseline spectrums to produce a time-series of normalized baseline spectrums. As another example, each of the baseline spectrum(s) obtained at box 210 may be divided by the average baseline spectrum to produce normalized baseline spectrum(s). In other words, the background noise represented by the average baseline spectrum is removed from each of the baseline spectrum(s) obtained at box 210.

Also illustrated at FIG. 2A, cleaning process 200 continues at box 250 wherein the cleaning process spectrum(s) obtained at box 230 are normalized. For example, the average baseline spectrum may be subtracted from each of the time-series of cleaning process spectrums to produce a time-series of normalized cleaning process spectrums. As another example, the each of the cleaning process spectrum(s) obtained at box 230 may be divided by the average baseline spectrum to produce normalized cleaning process spectrum(s). In other words, the background noise represented by the average baseline spectrum is removed from each of the cleaning process spectrum(s) obtained at box 230.

FIG. 2B illustrates a further portion of cleaning process 200. At box 245 a distribution value of the normalized baseline spectrum(s) is computed. A distribution value for each of the normalized baseline spectrum(s) may be calculated as a probability function (e.g., standard deviation, interquartile range, range, variance, coefficient of variation, skewness, and/or any function that generally describes the distribution or possibility of signal data) of normalized radiation intensity values at all wavelengths included in the particular normalized baseline spectrum. The distribution values for each of the normalized baseline spectrum(s) may then be combined (e.g., averaged) to compute a distribution value representative of all of the normalized baseline spectrum(s).

Also illustrated at FIG. 2B, cleaning process 200 continues at box 255 wherein a distribution function of the normalized cleaning process spectrum(s) is computed. A distribution value for each of the normalized cleaning process spectrum(s) may be calculated as a probability function (e.g., standard deviation, interquartile range, range, variance, coefficient of variation, skewness, and/or any function that generally describes the distribution or possibility of signal data) of normalized radiation intensity values at all wavelengths included in the particular normalized cleaning process spectrum. The distribution function of the normalized cleaning process spectrum(s) may include (e.g., represent as a time function) the distribution value(s) for each of the normalized cleaning process spectrum(s) over time.

At box 260, the distribution value of the normalized baseline spectrum(s) is compared with the distribution function of the normalized cleaning process spectrum(s). It should be appreciated that the end point EP of the cleaning process 200 may be reached when, near the end of the cleaning process 200, the noise level of the background is substantially similar to or equal to the reaction radiation detected at a particular instant. For example, the end point EP may be reached when, for a given point in time, the distribution value of the normalized baseline spectrum(s) is substantially similar or equal to the value of the distribution function of the normalized cleaning process spectrum(s) at that point in time. In some embodiments, a spectrum ratio R may be utilized to indicate when the distribution value of the normalized baseline spectrum(s) is substantially similar to or equal to the value of the distribution function of the normalized cleaning process spectrum(s). For example, the spectrum ratio R may be, at a given point in time, a ratio of the distribution value of the normalized baseline spectrum(s) to the value of the distribution function of the normalized cleaning process spectrum(s) at that point in time. The spectrum ratio R may be computed for each normalized cleaning process spectrum(s) and tracked over time as a spectrum ratio function R(t).

Before binding reactions begin, near the beginning of the cleaning process 200, the value of the distribution function of the normalized cleaning process spectrum should be similar to the distribution value of the normalized baseline spectrum, and the spectrum ratio R should be near 1. As binding reactions begin, during cleaning process 200, the radiation detected and measured by the normalized cleaning process spectrum increases, and the spectrum ratio R drops below 1. As contaminants are depleted from the processing volume, near the end of cleaning process 200, the rate of binding reactions drops, and the spectrum ratio R again approaches 1. Once binding reactions cease due to depletion of contaminants, the value of the distribution function of the normalized cleaning process spectrum should be substantially similar to or equal to the distribution value of the normalized baseline spectrum, and the spectrum ratio R should stabilize at or near 1. The end point EP of the cleaning process 200 may be deemed to be reached when the spectrum ratio function R(t) stabilizes at or near 1.

It should be appreciated that some operational conditions may be more sensitive to contamination, and such processes may benefit from more extensive cleaning. Alternatively, other operational conditions may be more sensitive to time and/or cost factors, and such alternative processes may benefit from less extensive cleaning. Therefore, at box 270, a clean threshold may be optionally input to identify the acceptable contamination level following cleaning process 200. For example, a low clean threshold may be set so that the end point EP will be identified when the spectrum ratio R (near the end of a cleaning process) exceeds 0.60. As another example, a high clean threshold may be set so that the end point EP will be identified when the spectrum ratio R (near the end of a cleaning process) exceeds 0.95.

A person of ordinary skill in the art with the benefit of this disclosure should understand that the comparison at box 260 (i.e., comparing the distribution value of the normalized baseline spectrum(s) to the distribution function of the normalized cleaning process spectrum(s)) may be analyzed and/or computed according to a variety of mathematical constructs. As illustrated in FIG. 2B, cleaning process 200 computes the spectrum ratio R as a fraction having the distribution value of the normalized baseline spectrum in the numerator and the distribution function of the normalized cleaning process spectrum in the denominator. The spectrum ratio R varies with time t. For example, For a point in time tₓ during the cleaning process 200, the fraction R(tₓ) is computed as the distribution value of the normalized baseline spectrum value divided by the value of the distribution function of the normalized cleaning process spectrum value at time tₓ.

In some embodiments, processing system 100 (from FIG. 1) may be utilized in a series of processing-cleaning cycles. For example, a first processing-cleaning cycle may include deposition process wherein a first processing gas is utilized to deposit a first film. The first deposition process may be followed by a first cleaning process, similar to cleaning process 200 (from FIG. 2A-B). A second processing-cleaning cycle may then follow, wherein a second processing gas is utilized to deposit a second film, followed by a second cleaning process, similar to cleaning process 200. Subsequent processing-cleaning cycles may also follow.

In some embodiments, during a series of processing-cleaning cycles, conventional means (e.g., visual detection or single-wavelength measurement) may be utilized to determine the end point of the first cleaning process. The first cleaning process may conclude with an over-cleaning period. For example, the gas source 122 (from FIG. 1) may cease flow of cleaning gas before or when the end point is detected by conventional means. During the over-cleaning period, gas source 122 may halt gas flow or provide only purge gas to processing volume 111. Radiation detection device 180 may acquire baseline spectrum(s) during the over-cleaning period, thereby obtaining a baseline spectrum or a time-series of baseline spectrums as in box 210 (from FIG. 2A-B). The baseline spectrum(s) obtained during the over-cleaning period of the first cleaning process may be utilized for determining the end point as in cleaning process 200 for the second and subsequent processing-cleaning cycles.

It should be understood that the background radiation spectrum of processing system 100 (from FIG. 1) may drift over the course of several processing-cleaning cycles. Therefore, in some embodiments, during a series of processing-cleaning cycles, intensity spectrum(s) acquired during a prior over-cleaning period may be utilized to obtain baseline spectrum(s) for a subsequent cleaning process. For example, in a series of processing-cleaning cycles identified in order as n−1, n, n+1, intensity spectrum(s) acquired during the n−1 over-cleaning period may be utilized to obtain baseline spectrum(s) for the n cleaning process, and intensity spectrum(s) acquired during the n over-cleaning period may be utilized to obtain baseline spectrum(s) for the n+1 cleaning process.

While the foregoing is directed to embodiments of the disclosure, other and further embodiments of the disclosure may be devised without departing from the basic scope thereof.

What is claimed is:

1. A method comprising:
obtaining at least one normalized baseline spectrum for a processing volume of a processing chamber;
calculating a distribution value of the at least one normalized baseline spectrum;
obtaining a plurality of normalized cleaning process spectrums for the processing volume over a time period during a cleaning process of the processing chamber;
calculating a distribution function of the plurality of normalized cleaning process spectrums;
comparing the distribution value to the distribution function over the time period; and
determining an end point for the cleaning process by identifying when the distribution function approaches the distribution value.

2. The method of claim 1, wherein comparing the distribution value to the distribution function over the time period comprises:
calculating a spectrum ratio function from the distribution value and the distribution function, wherein the spectrum ratio function is the distribution value divided by the distribution function.

3. The method of claim 2, wherein identifying when the distribution function approaches the distribution value comprises identifying when the spectrum ratio function approaches 1.

4. The method of claim 2, wherein identifying when the distribution function approaches the distribution value comprises identifying when the spectrum ratio function exceeds a specified threshold.

5. The method of claim 1, wherein obtaining a plurality of normalized cleaning process spectrums comprises:
obtaining an average baseline spectrum;
obtaining a plurality of cleaning process spectrums for the processing volume during the time period; and
removing the average baseline spectrum from each of the plurality of cleaning process spectrums.

6. The method of claim 5, wherein removing the average baseline spectrum from each of the plurality of cleaning process spectrums comprises at least one of:
subtracting the average baseline spectrum from each of the plurality of cleaning process spectrums; and
dividing each of the plurality of cleaning process spectrums by the average baseline spectrum.

7. The method of claim 5, wherein obtaining an average baseline spectrum comprises:
obtaining a plurality of baseline spectrums for the processing volume when the processing chamber is dark; and
averaging the plurality of baseline spectrums.

8. The method of claim 1, wherein calculating the distribution function of the plurality of normalized cleaning process spectrums comprises:
for each of the plurality of normalized cleaning process spectrums, calculating a probability function of radiation intensity over a plurality of wavelengths; and
ordering the probability functions over the time period.

9. The method of claim 1, wherein calculating the distribution value of the at least one normalized baseline spectrum comprises:
for each of the at least one normalized baseline spectrum, calculating a probability function of radiation intensity over a plurality of wavelengths; and
averaging the probability functions.

10. The method of claim 1, wherein obtaining at least one normalized baseline spectrum comprises:
obtaining at least one baseline spectrum for the processing volume when the processing chamber is dark;
averaging the at least one baseline spectrum to generate an average baseline spectrum; and
removing the average baseline spectrum from each of the at least one baseline spectrum.

11. The method of claim 1, further comprising:
flowing a cleaning gas into the processing volume; and
based on the end point, stopping the flow of the cleaning gas.

12. A method comprising:
initiating a first processing-cleaning cycle for a processing chamber, wherein:
the first processing-cleaning cycle comprises a first over-cleaning period, and
a first plurality of baseline spectrums for a processing volume of the processing chamber are measured during the first over-cleaning period;
after the first processing-cleaning cycle, initiating a second processing-cleaning cycle for the processing chamber, wherein:
the second processing-cleaning cycle comprises a second cleaning process, and
a second plurality of cleaning process spectrums for the processing volume are measured during the second cleaning process; and
determining a second end point for the second cleaning process by:
calculating a distribution function of a second plurality of normalized cleaning process spectrums from the first plurality of baseline spectrums and the second plurality of cleaning process spectrums;
calculating a distribution value of a second normalized baseline spectrum from the first plurality of baseline spectrums;
comparing the distribution value of the second normalized baseline spectrum to the distribution function of the second plurality of normalized cleaning process spectrums; and
identifying when the distribution function of the second plurality of normalized cleaning process spectrums approaches the distribution value of the second normalized baseline spectrum.

13. The method of claim 12, wherein:
the second processing-cleaning cycle comprises a second over-cleaning period,
a second plurality of baseline spectrums for the processing volume of the processing chamber are measured during the second over-cleaning period, and
the method further comprises:
after the second processing-cleaning cycle, initiating a third processing-cleaning cycle for the processing chamber, wherein:
the third processing-cleaning cycle comprises a third cleaning process, and
a third plurality of cleaning process spectrums for the processing volume are measured during the third cleaning process; and
determining a third end point for the third cleaning process by:
calculating a distribution function of a third plurality of normalized cleaning process spectrums from the second plurality of baseline spectrums and the third plurality of cleaning process spectrums;
calculating a distribution value of a third normalized baseline spectrum from the second plurality of baseline spectrums;
comparing the distribution value of the third normalized baseline spectrum to the distribution function of the third plurality of normalized cleaning process spectrums; and
identifying when the distribution function of the third plurality of normalized cleaning process spectrums approach the distribution value of the third normalized baseline spectrum.

14. The method of claim 13, wherein:
identifying when the distribution function of the second plurality of normalized cleaning process spectrums approaches the distribution value of the second normalized baseline spectrum comprises identifying when the distribution function of the second plurality of normalized cleaning process spectrums is closer to the distribution value of the second normalized baseline spectrum than a second specified threshold,
identifying when the distribution function of the third plurality of normalized cleaning process spectrums approaches the distribution value of the third normalized baseline spectrum comprises identifying when the distribution function of the third plurality of normalized cleaning process spectrums is closer to the distribution value of the third normalized baseline spectrum than a third specified threshold, and
the second specified threshold is different from the third specified threshold.

15. The method of claim 12, further comprising:
after the second processing-cleaning cycle, initiating a third processing-cleaning cycle for the processing chamber, wherein:
the third processing-cleaning cycle comprises a third cleaning process, and
a third plurality of cleaning process spectrums for the processing volume are measured during the third cleaning process; and
determining a third end point for the third cleaning process by:
calculating a distribution function of a third plurality of normalized cleaning process spectrums from the first plurality of baseline spectrums and the third plurality of cleaning process spectrums;
comparing the distribution value of the second normalized baseline spectrum to the distribution function of the third plurality of normalized cleaning process spectrums; and
identifying when the distribution function of the third plurality of normalized cleaning process spectrums approaches the distribution value of the second normalized baseline spectrum.

16. The method of claim 12, wherein a first end point of the first cleaning process is obtained by visual detection or single-wavelength measurement of the processing volume during the first processing-cleaning cycle.

17. The method of claim 12, wherein the second processing-cleaning cycle comprises introducing a second processing gas into the processing volume before the second cleaning process.

18. The method of claim 12, wherein the second cleaning process comprises:
flowing a cleaning gas into the processing volume, and
based on the second end point, stopping the flow of the cleaning gas.

19. A method comprising:
initiating a cleaning process in a processing chamber, the cleaning process comprising flowing a cleaning gas into a processing volume of the processing chamber;
obtaining a normalized baseline spectrum for the processing volume;
measuring a plurality of intensity spectrums for the processing volume during the cleaning process;
using the plurality of intensity spectrums to calculate a plurality of normalized cleaning process spectrums for the processing volume;
comparing a distribution value of the normalized baseline spectrum to a distribution function of the plurality of normalized cleaning process spectrums; and
determining an end point for the cleaning process by identifying when the distribution function of the plurality of normalized cleaning process spectrums approaches the distribution value of the normalized baseline spectrum.

20. The method of claim 19, further comprising stopping the flow of the cleaning gas based on the end point.
